(19) United States
(12) Patent Application Publication
(10) Pub. No.: US 2026/0159957 A1
(43) Pub. Date: Jun. 11, 2026

(54) STRUCTURAL MEMBER

(71) Applicant: TOTO LTD., Fukuoka (JP)

(72) Inventors: Shun KATAOKA, Fukuoka (JP); Senri SAKAMOTO, Fukuoka (JP); Ryoto TAKIZAWA, Fukuoka (JP)

(73) Assignee: TOTO LTD., Fukuoka (JP)

(21) Appl. No.: 19/393,221

(22) Filed: Nov. 18, 2025

(30) Foreign Application Priority Data
Dec. 5, 2024 (JP) 2024-211983

(51) Int. Cl. C23C 24/04

(52) U.S. Cl. CPC C23C 24/04

(57) ABSTRACT

A structural member having sufficient durability against plasma is provided. The structural member 10 includes a base material 100 and a protective film 200 covering the surface 110 of the base material 100. The protective film 200 includes ytterbium oxide as a main component. In a diffraction pattern provided by analyzing the protective film 200 using X-ray diffraction, when the maximum intensity of the peak attributed to the (401) plane of a monoclinic crystal structure is defined as PM, and the maximum intensity of the peak attributed to the (222) plane of a cubic crystal structure is defined as PC, the structural member 10 satisfies PM/PC >0.38.

### CROSS-REFERENCE-TO-RELATED-APPLICATION

This application is based upon and claims the benefit of priority from Japanese Patent Application No. 2024-211983, filed on Dec. 5, 2024, the entire contents of which are incorporated herein by reference.

### FIELD

The present invention relates to a structural member.

### BACKGROUND

Durability against plasma is required for members constituting a semiconductor manufacturing apparatus, for example, members such as chamber inner walls and the like. Therefore, structural members having a protective film formed on the surface of a base material have been commonly used as the above members as disclosed in Japanese Patent Laid-Open No. 2022-166808. Materials, such as yttria, are often used as protective films.

### SUMMARY

The present inventors have been considering the use of ytterbium oxide as a material for protective films and further improvement in the durability of protective film against plasma.

The present invention has been made in view of such problems and an object of the present invention is to provide a structural member having sufficient durability against plasma.

To solve the above problem, the structural member of the present invention comprises a base material and a protective film covering the surface of the base material. The protective film comprises ytterbium oxide as a main component. In a diffraction pattern provided by analyzing the protective film using X-ray diffraction, when the maximum intensity of the peak attributed to the (401) plane of a monoclinic crystal structure is defined as PM, and the maximum intensity of the peak attributed to the (222) plane of a cubic crystal structure is defined as PC, the structural member satisfies PM/PC>0.38.

The experiments conducted by the present inventors have demonstrated that when the proportion of the monoclinic crystal structure is increased to such an extent that the ratio PM/PC>0.38 is satisfied, the durability of the protective film against plasma can be sufficiently improved.

According to the present invention, a structural member with sufficient durability against plasma can be provided.

### BRIEF DESCRIPTION OF THE DRAWINGS

FIG. 1 schematically illustrates a cross-section of the structural member;

FIG. 2 is a graph illustrating the relationship between the monoclinic crystal ratio of the protective film and the durability of the protective film against plasma;

FIG. 3 is a graph illustrating the relationship between the monoclinic crystal ratio of the protective film and the durability of the protective film against plasma;

FIG. 4 is a graph illustrating an analytical method using X-ray diffraction;

FIG. 5 is a graph illustrating an analytical method using X-ray diffraction;

FIG. 6 is a table listing film-forming conditions and the like when forming a protective film;

FIG. 7 shows micrographs illustrating the surface shape of the protective film; and

FIGS. 8A, 8B and 8C show micrographs illustrating the porosity of the protective film.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

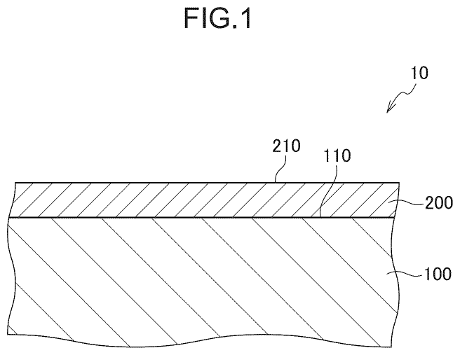

As shown in FIG. 1, the structural member 10 includes a base material 100 and a protective film 200. In a plasma etching apparatus or the like, the surface 210 of the protective film 200 is exposed to the interior of the process chamber. The protective film 200 is formed to protect the surface 110 of the base material 100 from plasma.

The base material 100 is a member forming the primary portion of the structural member 10. In the present embodiment, the base material 100 is a sintered ceramic body including high-purity aluminum oxide (Al₂O₃), but may be a different ceramic material or member other than a non-ceramic material (for example, a metal member). The surface 110 of the base material 100 is flat in the present embodiment, but may be curved or tapered in portions.

The protective film 200 is formed to protect the base material 100 from plasma as described above. The protective film 200 is formed to cover the entire surface 110 of the base material 100. The protective film 200 is composed of a material including ytterbium oxide (Yb₂O₃) as a main component. The ratio between the number of ytterbium (Yb) atoms and the number of oxygen (O) atoms in the protective film 200 may be different from the ratio described above. The protective film 200 of the present embodiment is formed by using an aerosol deposition method, but may be formed by another film-forming method.

As used herein, the “main component” refers to the compound contained in the greatest amount in the target object (in this case, protective film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (ytterbium oxide) in the protective film 200 of the present embodiment is more than 50% by volume or by mass. The proportion may be more than 70%, more than 90%, or may be 100%.

The thickness of the protective film 200 is appropriately adjusted depending on the duration for which durability is required to be maintained and other factors. In the present embodiment, the protective film 200 has a thickness of 15 μm or less. The thickness of may also be 1 μm or greater.

The present inventors have used ytterbium oxide as a material for the protective film 200 as in the present embodiment, and have been considering further improvement in the durability of the material against plasma. As a result, it has been confirmed that when the protective film 200 is formed using a material comprising ytterbium oxide as a main component, the durability of the protective film 200 against plasma varies depending on the crystal structure of the protective film 200. Specifically, the inventors have found that as the proportion of the monoclinic crystal structure in the protective film 200 increases, the durability of the protective film 200 against plasma improves.

The present inventors prepared multiple samples of the structural member 10 with varying crystal structures for the protective film 200, and assessed durability against plasma for each protective film 200. To evaluate the durability of the protective film 200 against plasma, the surface 210 of each protective film 200 was exposed to a plasma environment using an inductively coupling plasma reactive ion etching (ICP-RIE) system (not shown). The following two sets of conditions were employed when exposing the surface 210 to the plasma environment.

Under the first condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 30 minutes. The power output was set to 1,500 W for the ICP coil and 750 W for the bias. The plasma exposure test for the surface 210 of the protective film 200, performed under the first conditions described above, is called the “First Standard Plasma Test” below. In the First Standard Plasma Test, by setting the bias output to 750 W as described above, the plasma is drawn toward the protective film 200, and used for the etching of the protective film 200.

Under the second condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The

pressure in the chamber was adjusted to 0.5 Pa. The time of exposure was 60 minutes. The power output was set to 1,500 W for the ICP coil, and the bias output was turned off (i.e., 0 W). The plasma exposure test for the surface 210 of the protective film 200, performed under the second conditions described above, is called the “Second Standard Plasma Test” below. In the Second Standard Plasma Test, by turning off the bias output as described above, the plasma is not drawn toward the protective film 200, and hardly used for the etching of the protective film 200. The surface 210 of the protective film 200 is simply exposed to non-directional plasma.

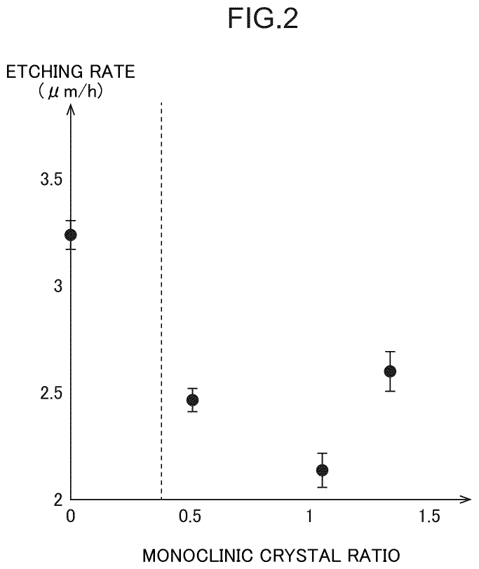

FIG. 2 shows the results of the First Standard Plasma Test described above conducted for each of the structural members 10. The “monoclinic crystal ratio” on the horizontal axis of the graph in FIG. 2 is an indicator of the proportion of the monoclinic crystal structure in the protective film 200. As the proportion of the monoclinic crystal structure in the protective film 200 increases, the monoclinic crystal ratio value increases. Specific definitions and calculation methods of the monoclinic crystal ratio will be described later.

The vertical axis of the graph in FIG. 2 represents the etching rate in the First Standard Plasma Test, specifically the depth to which the protective film 200 is etched per unit time, expressed in units of μm/h. The higher the durability of the protective film 200 against plasma, the smaller the etching rate of the protective film 200. The etching rate may be used as an indicator of the durability of the protective film 200 against plasma.

FIG. 2 shows the etching rates, with error bars, obtained from the First Standard Plasma Test for four samples with varying monoclinic crystal ratios of the protective film 200.

As FIG. 2 clearly shows, the larger the monoclinic crystal ratio value of the protective film 200, the smaller the etching rate of the protective film 200. For the protective films 200 with a monoclinic crystal ratio greater than 0.38, i.e., to the right of the dotted line in FIG. 2, the etching rate is sufficiently low, and sufficient durability against plasma was verified. The monoclinic crystal ratio may also be 3 or less.

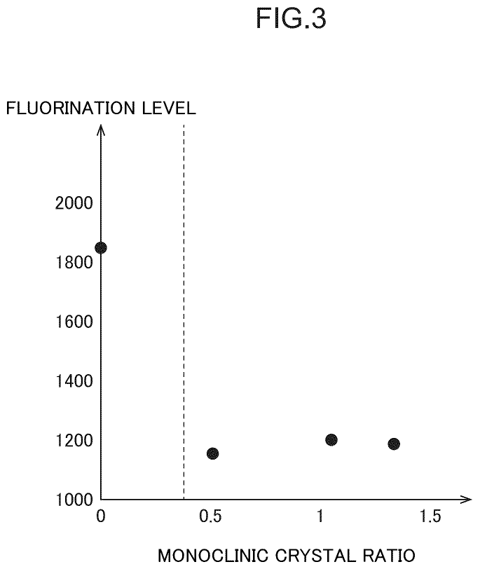

FIG. 3 shows the results of the Second Standard Plasma Test described above conducted for each of the structural members 10. The horizontal axis of the graph in FIG. 3 represents the monoclinic crystal ratio as in FIG. 2. The samples prepared for the Second Standard Plasma Test were prepared by the same method as for the samples prepared for the First Standard Plasma Test. Therefore, the monoclinic crystal ratio value of each sample shown in FIG. 3 is the same as the monoclinic crystal ratio value of each sample shown in FIG. 2.

The vertical axis of the graph in FIG. 3 represents the fluorination level of the protective film 200 after the Second Standard Plasma Test. The “fluorination level” is an indicator of how deep fluorine atoms, which are part of plasma, penetrate into the interior of the protective film 200. Specific measurement methods of the fluorination level are as follows.

First, while sputtering the surface 210 of the protective film 200 after the Second Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the durability of the protective film 200 against plasma, the smaller the value of the fluorination level calculated as described above. Like the etching rate described above, the fluorination level may be used as an indicator of the durability of the protective film 200 against plasma.

As FIG. 3 clearly shows, the larger the monoclinic crystal ratio value of the protective film 200, the smaller the fluorination level of the protective film 200. For the protective films 200 with a monoclinic crystal ratio greater than 0.38, i.e., to the right of the dotted line in FIG. 3, the fluorination level is sufficiently low, and sufficient durability against plasma was verified. The monoclinic crystal ratio may also be 3 or less.

The calculation method of the monoclinic crystal ratio will be described. The monoclinic crystal ratio is calculated from the results of the analysis of the crystal structure of the protective film 200 using X-ray diffraction.

The monoclinic crystal ratio of the protective film 200 was measured using the following method. First, X-ray diffraction (XRD) was performed on the protective film 200 formed on the base material 100 by out-of-plane measurement using a θ-2θ scan.

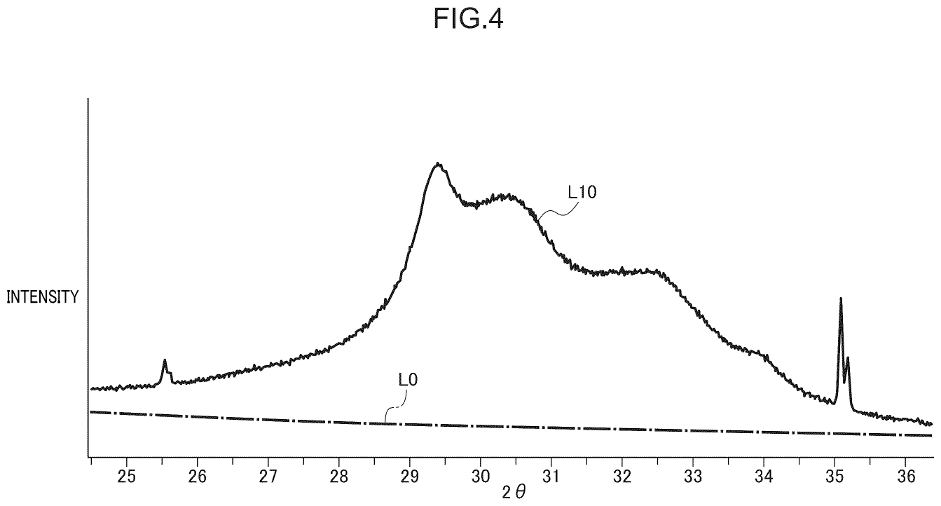

The line L10 in FIG. 4 is an example of the diffraction patterns provided by analyzing the protective films 200 using X-ray diffraction. This diffraction pattern is also referred to as “the measured diffraction pattern L10” below. A plurality of peaks are observed in the measured diffraction pattern L10, and each peak corresponds to the crystal structure of the material of the protective film 200. For example, the diffraction angles 2θ corresponding to the maximum of each peak are characteristic of the crystal structure of the protective film 200. The height of each peak corresponds to the proportion of the crystal structure associated with the diffraction angle 2θ in the protective film 200.

The “maximum intensity” of each peak may be used as is, as represented by the maximum intensity on the vertical axis of FIG. 4. However, to determine the proportion of the monoclinic crystal structure in the protective film 200 with higher accuracy, the following method is used to obtain the maximum intensity of each peak in the present embodiment.

The dash-dotted line L0 shown in FIG. 4 represents the background intensity in the absence of peaks. The profile of the dash-dotted line L0 can be inferred, for example, from the overall diffraction pattern.

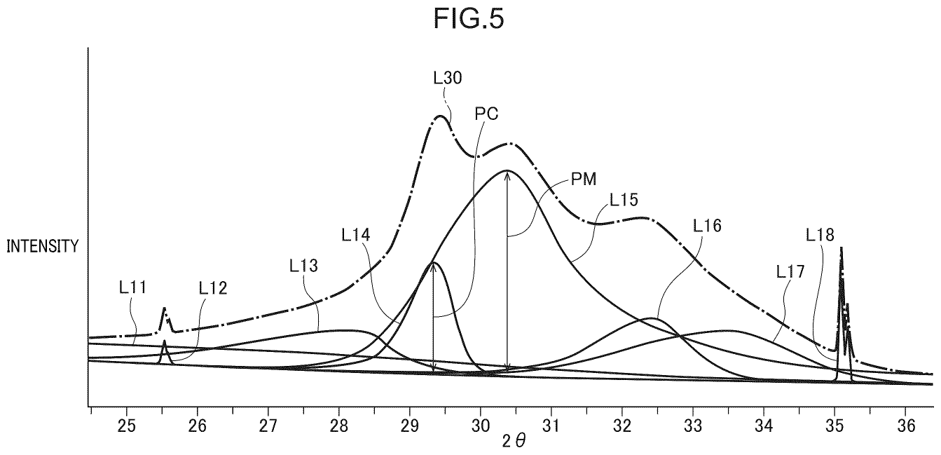

The line L11 shown in FIG. 5 represents a hypothetical diffraction pattern provided by adding only the peak with the maximum at a diffraction angle 2θ of 20.55° to the background represented by the dash-dotted line L0 in FIG. 4. The same applies to the lines L12 to L18 shown in FIG. 5, each line representing a hypothetical diffraction pattern provided by adding only the peak with the maximum at a specific diffraction angle 2θ to the background.

The diffraction angle 2θ of the peak of line L12 is 25.52°; the diffraction angle 2θ of the peak of line L13 is 28.33°; the diffraction angle 2θ of the peak of line L14 is 29.38°; the diffraction angle 2θ of the peak of line L15 is 30.24°; the diffraction angle 2θ of the peak of line L16 is 32.34°; the diffraction angle 2θ of the peak of line L17 is 33.4520; and the diffraction angle 2θ of the peak of line L18 is 35.09°.

The dash-dotted line 30 shown in FIG. 5 is a diffraction pattern provided by combining all the hypothetical diffraction patterns represented by the lines L11 to L18. This diffraction pattern is also referred to as “approximated diffraction pattern L30” below. When combining multiple hypothetical diffraction patterns, redundant background intensities are not added.

The hypothetical diffraction patterns represented by the lines L11 to L18 are individually adjusted so that the profile of the approximated diffraction pattern L30 provided by combining them substantially matches the measured diffraction pattern L10 shown in FIG. 4. In other words, by individually adjusting the diffraction angle 2θ at which the peak reaches the maximum and the height of the peak relative to the background for each line such as L11, the profile of the approximated diffraction pattern L30 is brought closer to the measured diffraction pattern L10. When the two profiles substantially match as a result of such adjustments, each hypothetical diffraction pattern represented by the lines L11 to L18 corresponds to a profile decomposed from the measured diffraction pattern L10 at each diffraction angle 2θ. Such a process may be performed manually while observing the profile of the approximated diffraction pattern L30, or may be performed automatically using the software functionality.

When the material of the protective film 200 is ytterbium oxide, the diffraction angle 2θ of the peak attributed to the (401) plane of the monoclinic crystal structure is known to be approximately 30.2°. Thus, in the example shown in FIG. 5, the peak attributed to the (401) plane of the monoclinic crystal structure can be inferred as the peak represented by the line L15.

The maximum intensity of the peak, in other words, the maximum intensity of the peak relative to the background, is also referred to as the “maximum intensity PM” below.

When the material of the protective film 200 is ytterbium oxide, the diffraction angle 2θ of the peak attributed to the (222) plane of the cubic crystal structure is known to be approximately 29.4°. Thus, in the example shown in FIG. 5, the peak attributed to the (222) plane of the cubic crystal structure can be inferred as the peak represented by the line L14. The maximum intensity of the peak, in other words, the maximum intensity of the peak relative to the background, is also referred to as the “maximum intensity PC” below.

Using the maximum intensity values PM and PC calculated by the method described above, the monoclinic crystal ratio is determined by the following equation (1).

$$Monoclinic crystal ratio = PM / PC \qquad ( 1 )$$

As described above, the maximum intensity PM refers to the maximum intensity of the peak attributed to the (401) plane of the monoclinic crystal structure. The maximum intensity PC refers to the maximum intensity of the peak attributed to the (222) plane of the cubic crystal structure. Therefore, the monoclinic crystal ratio determined by the above equation (1) can be used as an indicator of the proportion of the monoclinic crystal structure in the protective film 200. As described with reference to FIGS. 2 and 3, when the monoclinic crystal ratio=PM/PC>0.38 is satisfied for the protective film 200, a sufficient durability against plasma is achieved in the protective film 200. More preferably, when the protective film 200 is formed to satisfy PM/PC>0.50, the etching rate of the protective film 200 is further reduced.

The patterns shown in FIG. 4 and are examples for illustrating the definition and the calculation method of the monoclinic crystal ratio and do not correspond to the protective film 200 of the present embodiment.

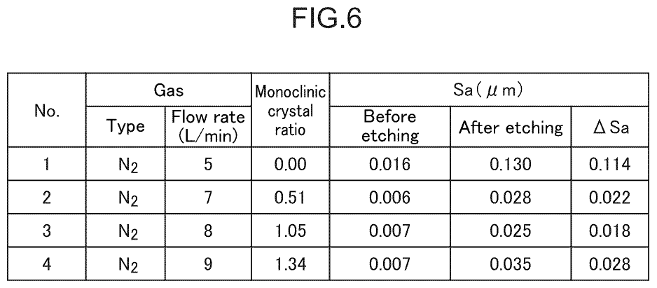

The method and other conditions for producing the samples used for obtaining the data shown in FIGS. 2 and 3 will be described with reference to FIG. 6. Sample No. 1 in FIG. 6 is a sample prepared under conditions such that the monoclinic crystal ratio of the protective film 200 was 0.00. Sample No. 2 is a sample prepared under conditions such that the monoclinic crystal ratio of the protective film 200 was 0.51; Sample No. 3 is a sample prepared under conditions such that the monoclinic crystal ratio of the protective film 200 was 1.05; and Sample No. 4 is a sample prepared under conditions such that the monoclinic crystal ratio of the protective film 200 was 1.34.

All of the protective film 200 samples No. 1 to 4 were formed by using an aerosol deposition method. As is well known, in the aerosol deposition method, fine particles constituting the protective film 200 are dispersed in a gas to form an aerosol, which is then sprayed from a nozzle toward the surface 110 to collide with it. At the surface 110, fine particles are deformed or fractured upon collision, bonding and depositing progressively to form the protective film 200. FIG. 6 shows the type of the gas described above used in the film-forming of the samples and the flow rate in spraying the gas from the nozzle.

A Yb₂O₃ powder was used as the “fine particles” described above. The powder had an average particle size of 3.0 μm and a median diameter of 2.4 μm.

As shown in FIG. 6, Samples No. 1 to 4 differ from one another in terms of the film-forming conditions for the protective film 200 (specifically, gas flow rates), resulting in distinct monoclinic crystal ratio of the protective film 200.

Samples No. 1 to 4 were each prepared in pairs. The First Standard Plasma Test was conducted on one of each pair, yielding the results shown in FIG. 2. The Second Standard Plasma Test was conducted on the other, yielding the results shown in FIG. 3.

The present inventors measured the arithmetic mean height (Sa) of the surface 210 for Samples No. 1 to 4 before and after conducting the First Standard Plasma Test. In the “Before etching” column of the table in FIG. 6, the arithmetic mean height of the surface 210, measured prior to the First Standard Plasma Test, is shown in μm. In the “After etching” column, the arithmetic mean height of the surface 210, measured after the First Standard Plasma Test, is shown in μm. In the “ΔSa” column, the difference in the above two arithmetic mean heights is shown. Namely, the amount of change in the arithmetic mean height of the surface 210 after conducting the First Standard Plasma Test is shown in μm. The method specified in ISO25178 was used as the measurement method of the arithmetic mean height.

For Sample No. 1, in which the monoclinic crystal ratio of the protective film 200 is 0.38 or less, the arithmetic mean height of the surface 210 of the protective film 200 after conducting the First Standard Plasma Test exceeds 0.1 μm. On the other hand, for Samples No. 2 to 4, in which the monoclinic crystal ratio of the protective film 200 is more than 0.38, the arithmetic mean height of the surface 210 of the protective film 200 after conducting the First Standard Plasma Test is less than 0.1 μm in all cases. The arithmetic mean height may also be 0.005 μm or greater.

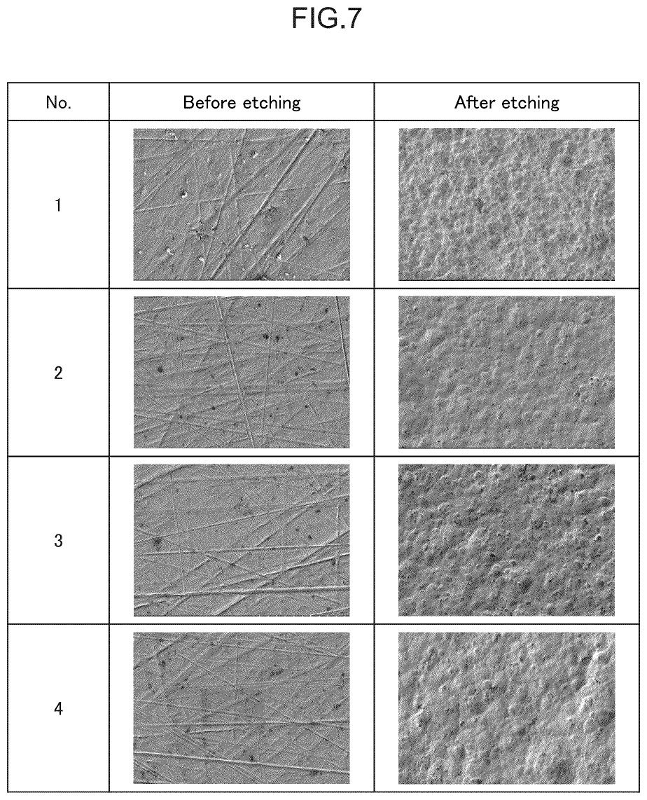

The present inventors observed the surface 210 of Samples No. 1 to 4 before and after conducting the First Standard Plasma Test using a scanning electron microscope (SEM). FIG. 7 shows images obtained from the observation. The images are what are called “secondary electron images,” which were obtained at an accelerated voltage of 3 kV. The magnification is 5,000×. Images from the observation before the First Standard Plasma Test are shown in the “Before etching” column in FIG. 7. Images from the observation after the First Standard Plasma Test are shown in the “After etching” column in FIG. 7.

The present inventors also measured the porosity of the protective film 200. The “porosity” as used herein refers to the proportion of the cross-sectional area occupied by pores, expressed as a percentage, in cross-sections of the protective film 200 cut in a plane perpendicular to the surface 210.

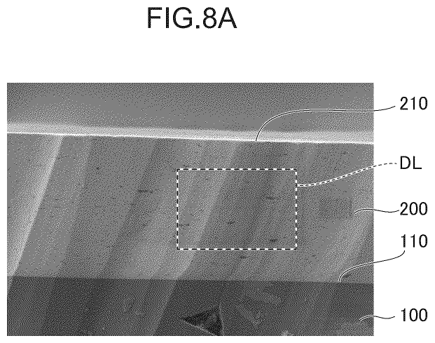

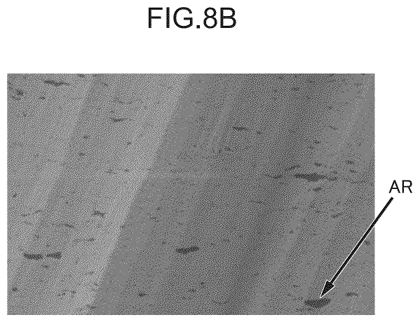

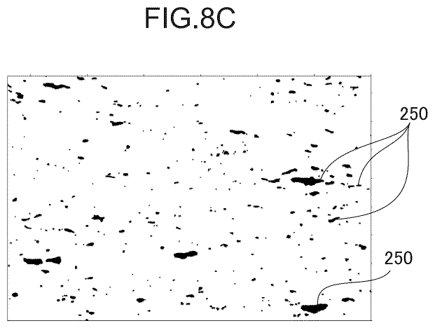

The method for measuring the porosity is as follows. First, the cross-sections described above are observed using a scanning electron microscope (SEM), and secondary electron images were provided. The accelerated voltage was 3 kV and the magnification was 30,000×. FIG. 8(A) shows an example of images provided by the procedure described above. The subject of the measurement is Sample No. 2 in the table in FIG. 6.

Next, by analyzing the images provided as described above, the porosity of the protective film 200 was calculated. Image analysis was performed using the OpenCV library in Python. The images were cropped to contain only the cross-section of the protective film 200. Specifically, regions outside the dotted line DL in FIG. 8(A) were cropped.

FIG. 8(B) shows the image after the cropping described above. The entire image consists of the cross-section of the protective film 200. In the image of FIG. 8(B), dark spots, one of which is indicated by arrow AR, are the cross-sections of pores contained within the protective film 200.

After cropping, the image of FIG. 8(B) was binarized to render the cross-sections of pores as black and other regions as white. The binarization was performed by applying the “Variable Threshold Binarization method” described in The Journal of the Institute of Image Electronics Engineers of Japan, 36(3), pp. 204-209, 2007. Subsequently, noise pixels were removed by dilation or other measures, yielding the binary image shown in FIG. 8(C). In FIG. 8(C), the black spots labeled 250 represent the cross-sections of pores contained within the protective film 200.

The ratio of black pixels to total pixels in the image of FIG. 8(C) was determined as the porosity of the protective film 200. In the example of FIG. 8(C), the total number of pixels of the image was 1,100,800 with 35,180 black pixels. Therefore, the porosity was determined as approximately 3.19%. The present inventors have demonstrated that when the monoclinic crystal ratio of the protective film 200 exceeds 0.38 and the porosity of the protective film 200 is 3.2% or less, the durability of the protective film 200 against plasma can be further improved. The porosity may also be 0.01% or greater.

The present inventors have also demonstrated that by forming the protective film 200 so that the average crystallite size is 50 nm or less, the durability of the protective film 200 against plasma can be further improved. The “average crystallite size” refers to the average diameter of the circles provided by performing circular approximation on at least 15 crystallites present on the surface 210 of the protective film 200. To calculate the average crystallite size of the protective film 200, the surface 210 of the protective film 200 is imaged using a Transmission Electron Microscope (TEM), and the average crystallite size can be calculated based on the acquired images. In this case, the magnification should be 400,000× or higher. The average crystallite size may also be 5 nm or greater.

By forming the protective film 200 to have an average crystallite size of 30 nm or less, and more preferably 15 nm or less, the durability of the protective film 200 can be further improved.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a base material, and
a protective film covering a surface of the base material,
wherein the protective film comprises ytterbium oxide as a main component, and
in a diffraction pattern provided by analyzing the protective film using X-ray diffraction,
PM/PC>0.38 is satisfied,
where PM represents a maximum intensity of a peak attributed to the (401) plane of a monoclinic crystal structure and PC represents a maximum intensity of a peak attributed to the (222) plane of a cubic crystal structure.

2. The structural member according to claim 1, wherein the protective film is formed by using an aerosol deposition method.

3. The structural member according to claim 1, wherein PM/PC>0.50 is satisfied.
